(19) United States
(12) Patent Application Publication
(10) Pub. No.: US 2022/0270913 A1
(43) Pub. Date: Aug. 25, 2022

(54) WAFER-HOLDING DEVICE AND THIN-FILM-DEPOSITION EQUIPMENT USING THE SAME

(71) Applicant: SKY TECH INC., Hsinchu County (US)

(72) Inventors: JING-CHENG LIN, Hsinchu County (TW); YU-TE SHEN, Hsinchu County (TW); TA-HAO KUO, Hsinchu County (TW); CHI-HUNG CHENG, Hsinchu County (TW)

(21) Appl. No.: 17/334,783

(22) Filed: May 30, 2021

(30) Foreign Application Priority Data
Feb. 22, 2021 (TW) 110106092

(51) Int. Cl. H01L 21/687; H01J 37/32; C23C 14/34; C23C 14/50

(52) U.S. Cl. CPC H01L 21/68721; H01L 21/68707; H01L 21/68742; H01J 37/32715; C23C 14/34; C23C 14/50; H01J 37/34

(57) ABSTRACT

The present disclosure provides a wafer-holding device, which mainly includes a wafer carrier, a first lid ring and a second lid ring, wherein the wafer carrier includes a carrying surface for carrying a wafer. The second lid ring is connected to the first-lid ring and placed on a radial-inner side of the first lid ring, wherein the first lid ring has a circumference larger than that of the second lid ring, for carrying the second lid ring. When the wafer carrier moves toward the first lid ring and the second lid ring, the second lid ring contacts the wafer on the wafer carrier, to fasten the wafer on the carrying surface of the wafer carrier, for performing a thin-film deposition to the wafer.

### TECHNICAL FIELD

The present disclosure relates to a wafer-holding device, more particularly a thin-film-deposition equipment using the wafer-holding device, for fastening a wafer on the wafer carrier and performing a thin-film deposition thereto.

### BACKGROUND

In manufacturing of integrated circuits, light-emitting diodes and displays, etc., thin-film-deposition equipments, such as chemical vapor deposition (CVD), physical vapor deposition (PVD) and atomic-layer deposition (ALD) equipments are commonly employed.

A deposition equipment mainly includes a chamber and a wafer carrier, wherein a wafer carrier is positioned within the chamber for carrying at least one wafer. For example in PVD, it is required to dispose a target material in the chamber and have the target material facing the wafer on the wafer carrier. When performing the PVD, the wafer is fastened on the wafer carrier by a holding device, then a noble gas and/or reactive gas may be transferred into the chamber, and then biases are respectively applied on the target material and the wafer carrier, moreover the wafer carrier can also heat up the wafer carried thereby. The noble gas within the chamber is ionized by an effect of high-voltage electric field, such that to form ionized gas. Then, the ionized noble gas is attracted by the bias applied on the target material to blast the target material. On next, atoms or molecules flying out from the target material are attracted by the bias on the wafer carrier, and deposited on a surface of the heated-up wafer to form a thin film on the surface of the wafer.

Generally, common thin-film-deposition equipments from industrial makers are merely adapted to process wafers with one single size. As for performing deposition to process a wafer with different size, many reconfigurations are required to apply on a structure the currently using thin-film-deposition equipment, or even must to purchase a different type of thin-film-deposition equipment, which can cause inconvenience in use, and large cost in manufacturing process.

### SUMMARY

As described in the background, the conventional thin-film-deposition equipments are commonly adapted to wafers in one single size only, therefore inconvenient for the use and costly for the manufacturing process. Hence, the present disclosure provides a new wafer-holding device and a thin-film-deposition equipment using the same, which can be adapted to fasten wafers with two or more different sizes and perform deposition, such that to improve utility of the wafer-holding device and the thin-film-deposition equipment, also to reduce and save the cost.

An object of the present disclosure is to provide a wafer-holding device, which mainly includes a wafer carrier, a first lid ring and a second lid ring, wherein the wafer carrier is for carrying at least one wafer. The first lid ring is for carrying the second lid ring, wherein the second lid ring has a circumference or radius smaller than that of the first lid ring and is placed inside of the first lid ring. When the wafer carrier moves the wafer carried on thereby toward the second lid ring, the second lid ring contacts the wafer, and fasten the wafer on the wafer carrier.

In practical use, the second lid ring can be removed from the first lid ring, and the first lid ring with larger radius or circumference can fasten a wafer with a larger size on the wafer carrier. Moreover, when the second lid ring is placed on the first lid ring, the second lid ring with smaller radius or circumference is fastened on the wafer carrier, such that the wafer-holding device is adapted to fasten wafers with two different sizes and perform thin-film deposition. Additionally, the second lid ring has a weight less than that of the first lid ring or a total weight of the first lid ring and the second lid ring, thereby to avoid damaging the wafer while fastening on the wafer carrier.

An object of the present disclosure is to provide a wafer-holding device, which mainly includes a wafer carrier and a carrying member. The wafer carrier has a carrying surface for carrying at least one wafer, and the carrying member is disposed on the wafer carrier and below the wafer.

The carrying member is connected to at least one elevating unit, and moved by the elevating unit related to the wafer carrier. When the carrying member is driven by the elevating unit to leave the wafer carrier, the carrying member moves the wafer to leave the carrying surface of the wafer carrier, to allow a robotic arm to take out the wafer on the carrying member, or to place the wafer on the carrying member. Thereafter the elevating unit can drive the carrying member toward the wafer carrier, and place the wafer on the carrying surface on the wafer carrier.

To achieve the abovementioned object, the present disclosure provides a wafer-holding device, for carrying and fastening at least one wafer. The wafer-holding device includes a wafer carrier, a first lid ring, and second lid ring. The wafer carrier includes a carrying surface for carrying the wafer. The first lid ring is positioned above the wafer carrier. The second lid ring is connected to the first lid ring and placed on a radial-inner side of the first lid ring, wherein the first lid ring has a circumference larger than that of the second lid ring for carrying the second lid ring. When the wafer carrier moves toward the second lid ring, the second lid ring contacts the wafer.

The present disclosure provides a thin-film-deposition equipment, which includes a chamber, at least one blocking member, a wafer-holding device, and a support member. The chamber includes a containing space. The blocking member is positioned within the containing space of the chamber, wherein the blocking member has an end formed with an annular flange, the annular flange is formed with an opening on a radial-inner side thereof. The wafer-holding device is positioned within the containing space, for carrying at least one wafer, and includes: a wafer carrier including a carrying surface for carrying the wafer; a first lid ring disposed on the annular flange of the blocking member; and a second lid ring connected to the first lid ring and placed on a radial-inner side of the first lid ring, wherein the first lid ring has a circumference larger than that of the second lid ring for carrying the second lid ring. The support member is connected to and moves the wafer carrier related to the blocking member, wherein when the support member moves the wafer carrier toward the blocking member, the second lid ring contacts the wafer.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a schematic perspective exploded view of one embodiment of a wafer-holding device, according to one embodiment of the present disclosure.

FIG. 2 is a schematic fragmentary sectional view of the wafer-holding device, according to one embodiment of the present disclosure.

FIG. 3 is a schematic fragmentary sectional view of wafer-holding device, according to another embodiment of the present disclosure.

FIG. 4-FIG. 6 are schematic perspective sectional view illustrating different position states of the wafer-holding device, according to one embodiment of the present disclosure.

FIG. 7 is a schematic sectional view of a thin-film-deposition equipment according to one embodiment of the present disclosure.

### DETAILED DESCRIPTION OF THE PREFERRED EMBODIMENTS

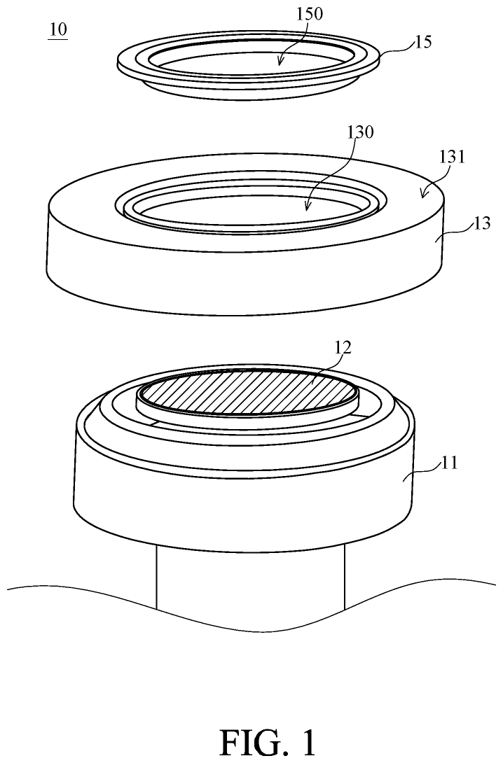

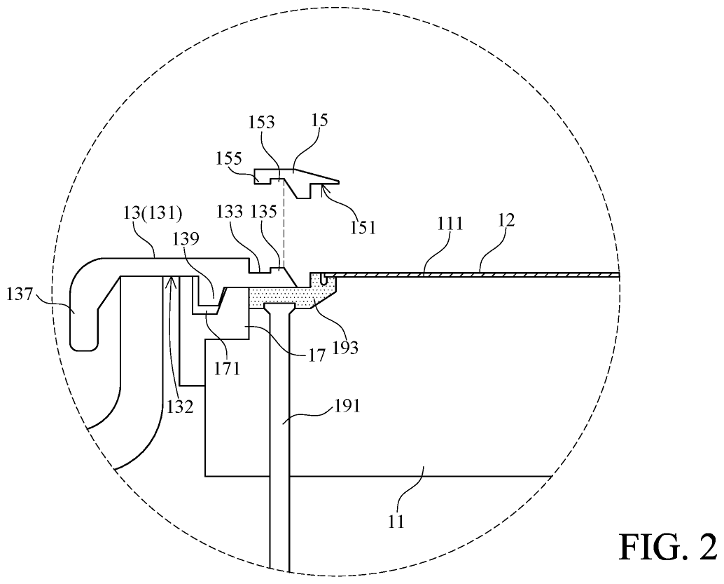

Referring to FIG. 1 and FIG. 2, which are a schematic perspective exploded view of one embodiment of a wafer-holding device, and a schematic fragmentary sectional view of the wafer-holding device, according to one embodiment of the present disclosure. As shown by FIGs, the wafer-holding device 10 is for carrying and fastening at least one wafer 12, and mainly includes at least one wafer carrier 11, a first lid ring 13 and a second lid ring 15, wherein the first lid ring 13 and the second lid ring 15 are positioned above the wafer carrier 11 and the wafer 12.

The wafer carrier 11 includes a carrying surface 111, for carrying the wafer 12. The first lid ring 13 and the second lid ring 15 are annular from a top view angle. The first lid ring 13 has a maximum circumference and/or maximum radius larger than that of the second lid ring 15. The second lid ring 15 is positioned above the first lid ring 13, and the second lid ring 15 is carried on by the first lid ring 13. When the wafer carrier 11 moves toward the first lid ring 13 and/or the second lid ring 15, the second lid ring 15 contacts an edge of the wafer 12 which is carried on by the wafer carrier 11, to fasten the wafer 12 on the carrying surface 111 of the wafer carrier 11.

Specifically, the first lid ring 13 includes a first opening 130, and the second lid ring 15 includes a second opening 150. The first opening 130 has a radius, circumference and/or area larger than that of the second opening 150, and the second lid ring 15 has a maximum radius and/or maximum circumference larger than that of the first opening 130. Therefore, the second lid ring 15 can be disposed or placed on a radial-inner side of the first lid ring 13, wherein when the second lid ring 15 is placed on the first lid ring 13, a portion on a radial-inner side of the second lid ring 15 protrudes from the radial-inner side of the first lid ring 13, to partially cover the first opening 130, such as a portion of the second lid ring 15 protrudes radially inward from the first lid ring 13.

The second lid ring 15 has a weight, which is less than a weight of the first lid ring 13 or less than a total weight of the first lid ring 13 and the second lid ring 15, wherein the second lid ring 15 or both of the first lid ring 13 and the second lid ring 15 apply a relatively small force on the wafer 12, such that to prevent the wafer 12 from receiving an excessive pressure/stress and resulting in damage. Therefore, the wafer-holding device 10 according the present disclosure is especially adapted to fasten wafers 12 with relative thin thickness on the wafer carrier 11.

In one embodiment of the present disclosure, the first lid ring 13 includes at least one first aligning portion, and the second lid ring 15 includes at least one second aligning portion. When the second lid ring 15 is placed on the first lid ring 13, the second aligning portion aligns with the first aligning portion and hence the second lid ring 15 and the first lid ring 13 are aligned.

As shown in FIG. 2, the first aligning portion of the first lid ring 13 includes at least one first cavity 133 and/or at least one first protrusion 135. The first cavity 133 and/or the first protrusion 135 is disposed on an upper surface 131 of the first lid ring 13. The second aligning portion of the second lid ring 15 includes at least one second cavity 153 and/or at least one second protrusion 155. The second cavity 153 and/or the second protrusion 155 is disposed on the a lower surface 151 of the second lid ring 15, such as the first cavity 133 and the second cavity 153 are annular grooves, the first protrusion 135 and the second protrusion 155 are annular protrusions.

The first cavity 133 and/or the first protrusion 135 of the first lid ring 13 respectively corresponds to the second protrusion 155 and/or the second cavity 153 of the second lid ring 15. The first cavity 133 and the second protrusion 155 have similar cross-sectional shapes, second cavity 153 and the first protrusion 135 has similar cross-sectional shapes. Also for example, the second cavity 153 has a wide entry area (downside of FIG. 2) and a narrow deep-inner area (upside of FIG. 2), in the other hand, the first protrusion 135 has a wide root area (downside of FIG. 2) and a narrow peak area (upside of FIG. 2), wherein each of the first protrusion 135 and the second cavity 153 has at least one inclined plane. When the second lid ring 15 is placed on the first lid ring 13, the first cavity 133, the first protrusion 135, the second protrusion 155 and/or the second cavity 153 can guide the second lid ring 15 to a locking position on the first lid ring 13, to complete a connection of the first lid ring 13 and the second lid ring 15.

Furthermore, the first lid ring 13 may has a lower surface 132 disposed with at least one flange 137 and at least one third protrusion 139, wherein the flange 137 and the third protrusion 139 may be annular protrusions. In one embodiment of the present disclosure, the flange 137 is connected to an outer edge of the first lid ring 13, and the third protrusion 139 is positioned in a radial-inner side of the flange 137.

In practical use, the second lid ring 15 can be placed on the first lid ring 13, to fasten a wafer 12 with a smaller size on the wafer carrier 11 via the second lid ring 15. Furthermore, the second lid ring 15 can also be removed from the first lid ring 13, to fasten a wafer 12 with a larger size on the wafer carrier 11 via the first lid ring 13. Also, when fastening the wafer 12 with larger size on the wafer carrier 11 via the first lid ring 13, the wafer carrier 11 may also be required to replace or dispose with other additional components.

In one embodiment the present disclosure, the wafer-holding device 10 may include an annular member 17, wherein the annular member 17 is connected to the wafer carrier 11 and disposed to surround the carrying surface 111 of the wafer carrier 11 and/or wafer 12, such as the annular member 17 be mounted on a portion of the wafer carrier 11, as shown in FIG. 2.

Each of the annular member 17 and the first lid ring 13 include at least one aligning portion corresponding to each other, for aligning the annular member 17 with the first lid ring 13. For example, an upper surface of the annular member 17 may include at least one third cavity 171, wherein the third cavity 171 corresponds to the third protrusion 139 of the first lid ring 13, and for guiding the first lid ring 13 and the second lid ring 15 to a locking position on the wafer carrier 11, thereby the second lid ring 15 contacts and fastens the wafer 12 on the wafer carrier 11.

In one embodiment of the present disclosure, the wafer-holding device 10 may include at least one elevating unit 191 and a carrying member 193. The carrying member 193 is disposed on the wafer carrier 11 and below the wafer 12 carried on by the wafer carrier 11, for example the carrying member 193 may have an annular appearance and be positioned on a radial-inner side of the annular member 17. The elevating unit 191 is connected to the carrying member 193 and the wafer carrier 11, for moving the carrying member 193 related to the wafer carrier 11. For example, the elevating unit 191 can extend related to the carrying surface 111 of the wafer carrier 11, and moves the carrying member 193 away from the wafer carrier 11, thereby to ascend and move the wafer 12 away from the carrying surface 111 of the wafer carrier 11 via the carrying member 193.

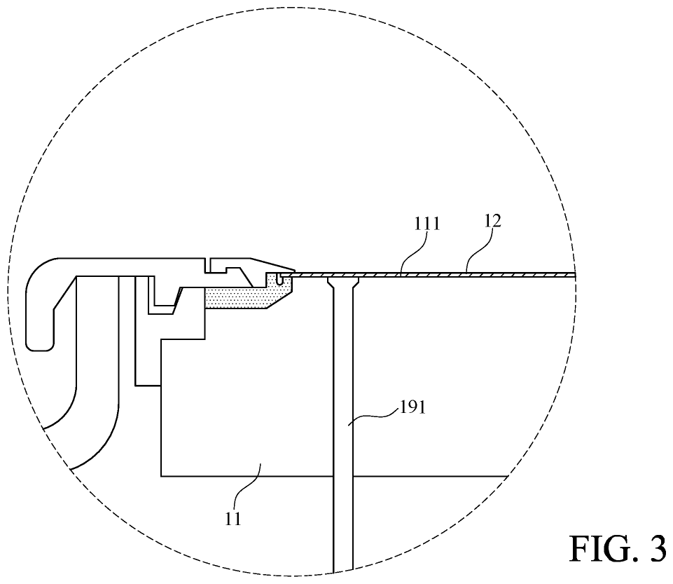

In another embodiment of the present disclosure as shown in FIG. 3, the elevating unit 191 is connected to the wafer carrier 11 and below the wafer 12 carried on by the wafer carrier 11. The elevating unit 191 can extend related to the carrying surface 111 of the wafer carrier 11, to ascend and move the wafer 12 away from the carrying surface 111 of the wafer carrier 11, such that there is no need to dispose the carrying member 193.

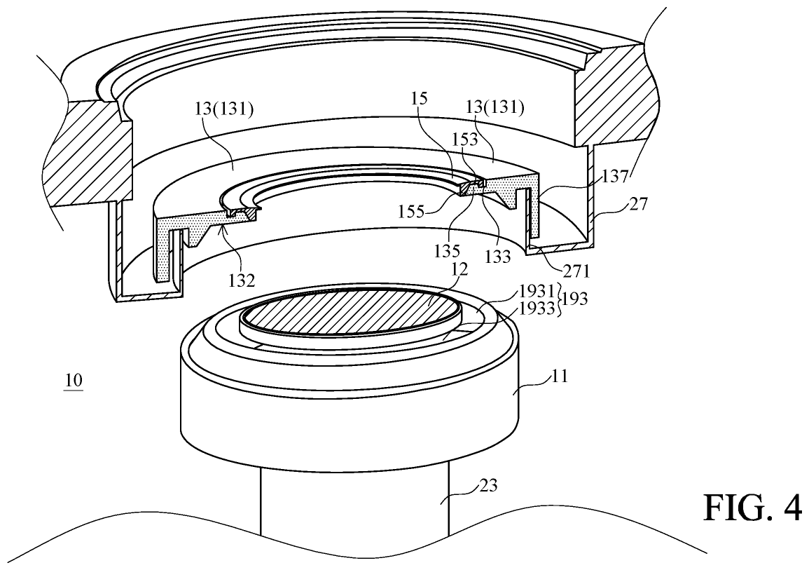

In practical use, as shown in FIG. 2 and FIG. 4, the first lid ring 13 may be placed on a blocking member 27, wherein the blocking member 27 has an end formed with an annular flange 271. The annular flange 271 of the blocking member 27 is positioned between the flange 137 and the third protrusion 139 of the first lid ring 13, for carrying the first lid ring 13.

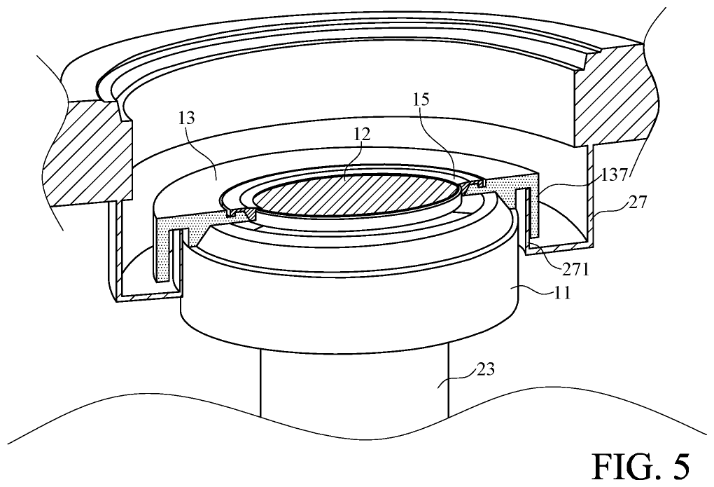

The wafer carrier 11 is connected to a support member 23, wherein the support member 23 is for moving the wafer carrier 11, related to the blocking member 27 also the first lid ring 13 and second lid ring 15 carried on thereby, as shown in FIG. 5. Such that, the second lid ring 15 contacts the wafer 12 carried on by the wafer carrier 11, to fasten the wafer 12 on the wafer carrier 11.

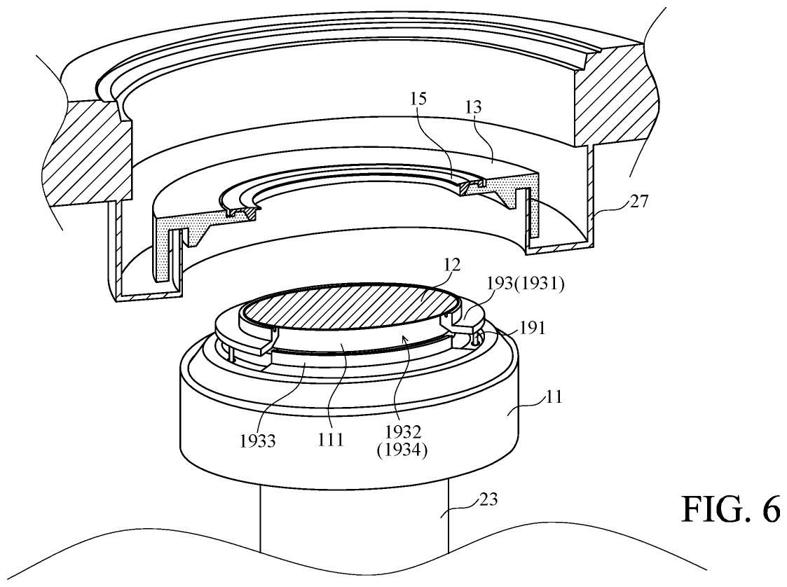

In one embodiment of the present disclosure as shown in FIG. 6, the support member 23 moves the wafer carrier 11 away from the blocking member 27, the first lid ring 13 and the second lid ring 15. Thereafter, the elevating unit 191 may further move the carrying member 193 away from the wafer carrier 11, thereby the carrying member 193 ascends to lift up the wafer 12 which was on the carrying surface 111 of the wafer carrier 11, and to form a gap space 1934 between the wafer 12 and the carrying surface 111 of the wafer carrier 11. A robotic arm (not shown) may enter the gap space 1934 below the wafer 12, to take out and extract the wafer 12 on the carrying member 193, or to place the wafer 12 on the carrying member 193.

After the robotic arm places the wafer 12 on the carrying member 193, the elevating unit 191 moves the carrying member 193 and the wafer 12 carried on thereby toward the carrying surface 111 of the wafer carrier 11, such that to place the wafer 12 on the carrying surface 111 of the wafer carrier 11, as shown in FIG. 4.

In another embodiment of the present disclosure, the carrying member 193 includes a first carrying portion 1931 and a second carrying portion 1933, wherein the first carrying portion 1931 includes a gap notch 1932, and the second carrying portion 1933 is positioned within the gap notch 1932. To be specific, the carrying member 193 may have an annular appearance, both of the first carrying portion 1931 and the second carrying portion 1933 may be partially annular, so when the second carrying portion 1933 is positioned within the gap notch 1932 of the first carrying portion 1931, both can form the carrying member 193 as a fully annular circle.

Moreover, the elevating unit 191 is only connected to the first carrying portion 1931, wherein the elevating unit 191 can move the first carrying portion 1931 and the wafer 12 to ascend away from the carrying surface 111 of the wafer carrier 11, to facilitate the robotic arm to extract the wafer 12 from the gap notch 1932 of the first carrying portion 1931, or to place the wafer 12 on the first carrying portion 1931 via the gap notch 1932.

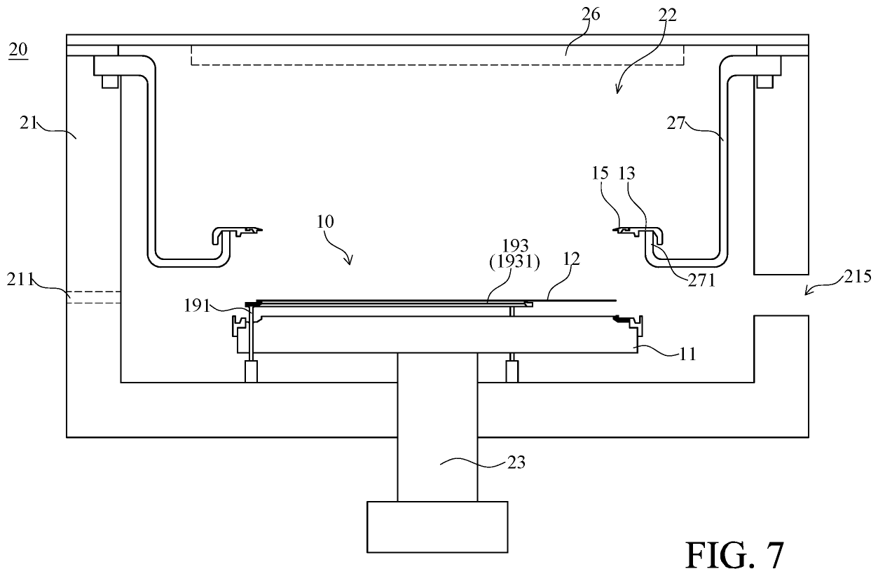

Referring to FIG. 7, which is a schematic sectional view of a thin-film-deposition equipment, according to the present disclosure. As shown in FIG, the thin-film-deposition equipment 20 includes at least one wafer-holding device 10 and a chamber 21, wherein the chamber 21 includes a containing space 22, and the wafer-holding device 10 is positioned within the containing space 22 for carrying at least one wafer 12.

As shown in FIG. 1, the wafer-holding device 10 mainly includes at least one wafer carrier 11, a first lid ring 13 and a second lid ring 15, wherein the first lid ring 13 and second lid ring 15 are positioned above the wafer carrier 11 and the wafer 12. The first lid ring 13 and the second lid ring 15 are annular from a top view angle, wherein the first lid ring 13 has a maximum circumference and/or maximum radius larger than that of the second lid ring 15.

The containing 22 of the chamber 21 is disposed with at least one blocking member 27 therein, wherein the blocking member 27 has an end connected to the chamber 21 and another end formed with an opening. In one embodiment of the present disclosure, the end of the blocking member 27 having no connection to the chamber 21, which may be formed with an annular flange 271 and also formed with an opening on a radial-inner side of the annular flange 271. The annular flange 271 of the blocking member 27 is for carrying the first lid ring 13, and the first lid ring 13 is for carrying the second lid ring 15.

In one embodiment of the present disclosure, the thin-film-deposition equipment 20 may be a physical-vapor-deposition equipment which has a target material 26 within the chamber 21, wherein the target material 26 faces the wafer carrier 11 and/or the wafer 12. The chamber 21 is disposed with at least one gas inlet 211, wherein the gas let 211 is fluidly connected to the containing space 22 of the chamber 21, for transferring a process gas into the containing space 22 to perform a thin-film deposition. The process gas may be such as noble gas, or reaction gas. In addition, the chamber 21 may be disposed with a gas outlet (not shown) thereon, for extracting the gas within the chamber 21 via a pump.

The chamber 21 may include a wafer passage 215, for transporting a wafer 12 into or extract the wafer 12 from the chamber 21, via the robotic arm.

In one embodiment of the present disclosure, the wafer carrier 11 is connected to a support member 23, wherein the support member 23 is for moving the wafer carrier 11 related to the blocking member 27, the first lid ring 13 and the second lid ring 15. As shown in FIG. 5, the support member 23 moves the wafer carrier 11 toward the blocking member 27, thereby the second lid ring 15 contacts the wafer 12 of the wafer carrier 11, to fasten the wafer 12 on the wafer carrier 11.

As shown in FIG. 6 and FIG. 7, the support member 23 moves the wafer carrier 11 away from the blocking member 27, the first lid ring 13 and the second lid ring 15. Thereafter, the elevating unit 191 may further move the carrying member 193 or the first carrying portion 1931 away from the wafer carrier 11, thereby the carrying member 193 or the first carrying portion 1931 ascends to lift up the wafer 12 which was on the carrying surface 111 of the wafer carrier 11, and to form a gap space 1934 between the wafer 12 and the carrying surface 111 of the wafer carrier 11, to facilitate a robotic arm (not shown) to extract the wafer 12 on the carrying member 193, or to place the wafer 12 on the carrying member 193, via the wafer passage 215.

After the robotic arm places the wafer 12 on the carrying member 193 or the first carrying portion 1931, the elevating unit 191 moves the carrying member 193 and the wafer 12 carried on thereby to descend toward the carrying surface 111 of the wafer carrier 11, to place the wafer 12 on the carrying surface 111 of the wafer carrier 11, as shown in FIG. 4.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

We claim:

1. A wafer-holding device for carrying and fastening at least one wafer, comprising:
a wafer carrier comprising a carrying surface for carrying the wafer;
a first lid ring positioned above the wafer carrier; and
a second lid ring connected to the first lid ring and placed on the first lid ring, wherein the first lid ring has a circumference larger than that of the second lid ring, the first lid ring is for carrying the second lid ring, and when the wafer carrier moves toward the second lid ring, the second lid ring contacts the wafer.

2. The wafer-holding device as claimed in claim 1, wherein the second lid ring has a weight less than that of the first lid ring.

3. The wafer-holding device as claimed in claim 1, wherein the first lid ring comprises a first opening, the second lid ring comprises a second opening, the first opening has a radius or an area larger than that of the second opening, and the second lid ring has a maximum radius or a maximum circumference larger than that of the first opening.

4. The wafer-holding device as claimed in claim 1, wherein the first lid ring comprises at least one first aligning portion, the second lid ring comprises at least one second aligning portion, and when the second lid ring is connected to the first lid ring, the at least one second aligning portion aligns with the at least one first aligning portion thereby the second lid ring and the first lid ring are aligned.

5. The wafer-holding device as claimed in claim 4, wherein the at least one first aligning portion of the first lid ring comprises at least one first cavity or at least one first protrusion, the at least one second aligning portion of the second lid ring comprises at least one second cavity or at least one second protrusion, and the at least one first cavity or at least one first protrusion of the first lid ring respectively corresponds to the at least one second protrusion or the at least one second cavity of the second lid ring.

6. The wafer-holding device as claimed in claim 5, wherein the at least one first protrusion of the first lid ring and the at least one second cavity of the second lid ring both comprise at least one inclined plane, for guiding the second lid ring to a locking position on the first lid ring.

7. The wafer-holding device as claimed in claim 1, comprising:
a carrying member disposed on the wafer carrier and below the wafer; and
at least one elevating unit connected to the carrying member for moving the carrying member related to the wafer carrier, wherein when the at least one elevating unit moves the carrying member away from the wafer carrier, the carrying member brings the wafer away from the carrying surface of the wafer carrier.

8. The wafer-holding device as claimed in claim 7, wherein the carrying member comprises a first carrying portion that comprises a gap notch and a second carrying portion that is positioned within the gap notch, and the at least one elevating unit is connected to the first carrying portion for moving the first carrying portion and the wafer related to the wafer carrier.

9. The wafer-holding device as claimed in claim 1, comprising an annular member connected to the wafer carrier, the annular member is positioned to surround the carrying surface of the wafer carrier, wherein each of the annular member and the first lid ring comprises at least one aligning portion corresponding to each other, for aligning the annular member with the first lid ring.

10. A thin-film-deposition equipment, comprising:
a chamber comprising a containing space;
at least one blocking member positioned within the containing space of the chamber, wherein the at least one blocking member has an end formed with an annular flange, and the annular flange is formed with an opening on a radial-inner side thereof;
a wafer-holding device positioned within the containing space for carrying at least one wafer and comprising
a wafer carrier comprising a carrying surface for carrying the wafer,
a first lid ring disposed on the annular flange of the at least one blocking member, and
a second lid ring connected to the first lid ring and placed on the first lid ring, wherein the first lid ring has a circumference larger than that of the second lid ring for carrying the second lid ring; and
a support member connected to and moves the wafer carrier related to the at least one blocking member, wherein when the support member moves the wafer carrier toward the at least one blocking member, the second lid ring contacts the wafer.

11. The thin-film-deposition equipment as claimed in claim 10, wherein the second lid ring has a weight less than that of the first lid ring.

12. The thin-film-deposition equipment as claimed in claim 10, wherein the first lid ring comprises a first opening, the second lid ring comprises a second opening, the first opening has a radius or an area larger than that of the second opening, and the second lid ring has a maximum radius or a maximum circumference larger than that of the first opening.

13. The thin-film-deposition equipment as claimed in claim 10, wherein the first lid ring comprises at least one first aligning portion; the second lid ring comprises at least one second aligning portion, and when the second lid ring is connected to the first lid ring, the at least one second aligning portion aligns with the at least one first aligning portion, thereby the second lid ring and the first lid ring are aligned.

14. The thin-film-deposition equipment as claimed in claim 13, wherein the at least one first aligning portion of the first lid ring comprises at least one first cavity or at least one first protrusion, the at least one second aligning portion of the second lid ring comprises at least one second cavity or at least one second protrusion, and the at least one first cavity or at least one first protrusion of the first lid ring respectively corresponds to the at least one second protrusion or the at least one second cavity of the second lid ring.

15. The thin-film-deposition equipment as claimed in claim 14, wherein each of the at least one first protrusion of the first lid ring and the at least one second cavity of the second lid ring respectively has at least one inclined plane, for guiding the second lid ring to a locking position on the first lid ring.

16. The thin-film-deposition equipment as claimed in claim 10, comprising an annular member connected to the wafer carrier, the annular member is positioned to surround the carrying surface of the wafer carrier, wherein each of the annular member and the first lid ring comprises at least one aligning portion corresponding to each other, for aligning the annular member with the first lid ring.

17. The thin-film-deposition equipment as claimed in claim 10, comprising:
a carrying member disposed on the wafer carrier and below the wafer; and
at least one elevating unit connected to the carrying member for moving the carrying member related to the wafer carrier, wherein when the at least one elevating unit moves the carrying member away from the wafer carrier, the carrying member brings the wafer away from the carrying surface of the wafer carrier.

18. The thin-film-deposition equipment as claimed in claim 17, wherein: the carrying member comprises a first carrying portion and a second carrying portion, the first carrying portion comprises a gap notch, and the second carrying portion is positioned within the gap notch; and the elevating unit is connected to the first carrying portion, for moving the first carrying portion and the wafer to ascend or descend related to the wafer carrier.

19. The thin-film-deposition equipment as claimed in claim 18, wherein the chamber comprises a wafer passage, for a robotic arm to transport the wafer into the chamber and place the wafer on or to extract the wafer from the first carrying portion of the carrying member moved by the elevating unit to ascend.

20. The thin-film-deposition equipment as claimed in claim 10, wherein the chamber is disposed with at least one gas inlet and a gas outlet, the at least one gas inlet is fluidly connected to the containing space for transferring a process gas into the containing space to perform a deposition process, and the gas outlet is for extracting the process gas within the chamber.
